(19) United States
(12) Patent Application Publication
(10) Pub. No.: US 2014/0020741 A1
(43) Pub. Date: Jan. 23, 2014

(54) SOLAR CELL AND METHOD FOR PRODUCING SOLAR CELL

(71) Applicant: Sanyo Electric Co., Ltd., Osaka (JP)

(72) Inventors: Isao Hasegawa, Akashi-shi (JP); Toshio Asaumi, Osaka (JP); Hitoshi Sakata, Osaka (JP)

(73) Assignee: Sanyo Electric Co., Ltd., Osaka (JP)

(21) Appl. No.: 14/034,711

(22) Filed: Sep. 24, 2013

Related U.S. Application Data
(63) Continuation of application No. PCT/JP2012/056095, filed on Mar. 9, 2012.

(30) Foreign Application Priority Data
Mar. 28, 2011 (JP) 2011-070195

(51) Int. Cl. H01L 31/0352; H01L 31/075

(52) U.S. Cl. CPC H01L 31/03529; H01L 31/075
USPC 136/255; 438/87

(57) ABSTRACT

A solar cell having improved carrier collection efficiency is provided. A solar cell (1) is provided with a semiconductor substrate (10) having one type of conductivity, a first semiconductor layer (12n), a second semiconductor layer (13p), a first electrode (14), and a second electrode (15). The first semiconductor layer (12n) is arranged on one main surface (10b) of the semiconductor substrate (10). The first semiconductor layer (12n) has the one type of conductivity. The second semiconductor layer (13p) is arranged on the one main surface (10b) of the semiconductor substrate (10). The second semiconductor layer (13p) has the other type of conductivity. The first electrode (14) is connected electrically to the first semiconductor layer (12n). The second electrode (15) is connected electrically to the second semiconductor layer (13p). The thickness of the second semiconductor layer (13p) is thinner than the thickness of the first semiconductor layer (12n).

### CROSS-REFERENCE TO RELATED APPLICATIONS

This is a continuation of International Application PCT/JP2012/056095, with an international filing date of Mar. 9, 2012, filed by applicant, the disclosure of which is hereby incorporated by reference in its entirety.

### FIELD OF THE INVENTION

The present invention relates to a solar cell and to a manufacturing method for a solar cell. The present invention relates more specifically to a back contact solar cell and to a manufacturing method for a back contact solar cell.

### BACKGROUND

Back contact solar cells are conventionally known (for an example, see Patent Document 1). A back contact solar cell does not require an electrode on the light-receiving surface. As a result, the light-receiving efficiency of back contact solar cells can be increased. Therefore, further improvement in photoelectric conversion efficiency can be realized.

### CITED DOCUMENTS

### Patent Documents

Patent Document 1: Laid-Open Patent Publication No. 2009-200267

### SUMMARY

### Problem Solved by the Invention

The collection efficiency for the minor carrier must be improved in order to further improve the photoelectric conversion efficiency of back contact solar cells.

In view of this situation, it is the object of the present invention to provide a solar cell having improved carrier collection efficiency.

### Means of Solving the Problem

The solar cell in the present invention includes a semiconductor substrate having one type of conductivity, a first semiconductor layer, a second semiconductor layer, a first electrode, and a second electrode. The first semiconductor layer is arranged on one main surface of the semiconductor substrate. The first semiconductor layer has the one type of conductivity. The second semiconductor layer is arranged on the one main surface of the semiconductor substrate. The second semiconductor layer has the other type of conductivity. The first electrode is connected electrically to the first semiconductor layer. The second electrode is connected electrically to the second semiconductor layer. The thickness of the second semiconductor layer is thinner than the thickness of the first semiconductor layer.

The present invention is also a method for manufacturing a solar cell in which a first semiconductor layer having one type of conductivity is formed on a portion of one main surface of a semiconductor substrate having the one type of conductivity. A semiconductor film having the other type of conductivity is formed on the one main surface of the semiconductor substrate including the first semiconductor layer. The first semiconductor layer is exposed by removing at least one part of the portion of the semiconductor film positioned on the first semiconductor layer, and a second semiconductor layer is formed from the semiconductor film. A first electrode is formed on the first semiconductor layer, and a second electrode is formed on the second semiconductor layer. The thickness of the second semiconductor layer is thinner than the thickness of the first semiconductor layer.

### Effect of the Invention

The present invention is able to provide a solar cell having improved carrier collection efficiency.

### BRIEF DESCRIPTION OF THE DRAWINGS

FIG. 1 is a schematic plan view of the back surface of the solar cell in a first embodiment of the present invention.

FIG. 2 is a schematic cross-sectional view from line II-II in FIG. 1.

FIG. 3 is a flowchart showing the manufacturing steps for the solar cell in the first embodiment.

FIG. 4 is a schematic cross-sectional view used to explain a manufacturing step for the solar cell in the first embodiment.

FIG. 5 is a schematic cross-sectional view used to explain a manufacturing step for the solar cell in the first embodiment.

FIG. 6 is a schematic cross-sectional view used to explain a manufacturing step for the solar cell in the first embodiment.

FIG. 7 is a schematic cross-sectional view used to explain a manufacturing step for the solar cell in the first embodiment.

FIG. 8 is a schematic cross-sectional view used to explain a manufacturing step for the solar cell in the first embodiment.

FIG. 9 is a schematic cross-sectional view used to explain a manufacturing step for the solar cell in the first embodiment.

FIG. 10 is a schematic cross-sectional view used to explain a manufacturing step for the solar cell in the first embodiment.

### DETAILED DESCRIPTION

The following is an explanation of a preferred embodiment of the present invention. The following embodiment is merely an example. The present invention is not limited to the following embodiment in any way.

Further, in each of the drawings referenced in the embodiment, members having substantially the same function are denoted by the same symbols. The drawings referenced in the embodiments are also depicted schematically. The dimensional ratios of the objects depicted in the drawings may differ from those of the actual objects. The dimensional ratios of objects may also vary between drawings. The specific dimensional ratios of the objects should be determined with reference to the following explanation.

### 1st Embodiment

### Configuration of Solar Cell 1

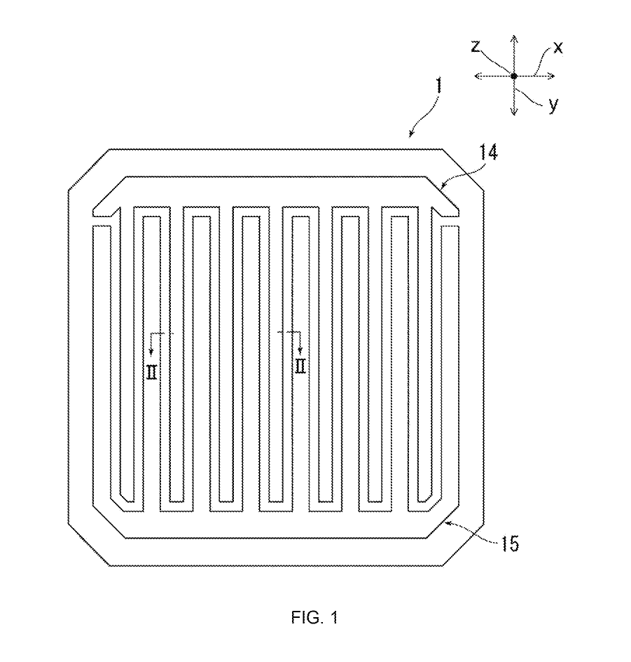

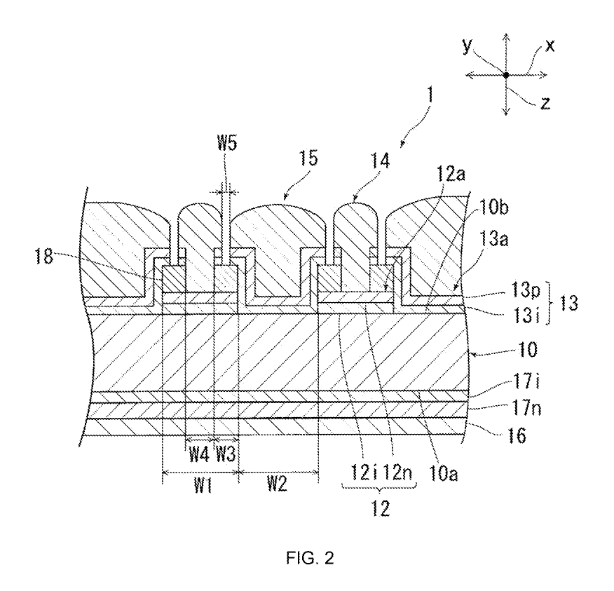

FIG. 1 is a schematic plan view of the back surface of the solar cell in a first embodiment of the present invention. FIG. 2 is a schematic cross-sectional view from line II-II in FIG. 1.

The solar cell 1 is a back contact solar cell. When a single solar cell 1 in the present embodiment does not yield sufficiently high output, the solar cell 1 is used as part of a solar cell module in which a plurality of solar cells 1 are connected by means of wiring material.

The solar cell 1 has a semiconductor substrate 10 made of a semiconducting material. The semiconductor substrate 10 has one type of conductivity. In other words, the semiconductor substrate 10 has either n-type or p-type conductivity. More specifically, in the present embodiment, the semiconductor substrate 10 consists of a wafer-shaped substrate made of n-type crystalline silicon. Crystalline silicon includes single-crystal silicon and polycrystalline silicon. The semiconductor substrate in the present invention is not limited to this example. The conductivity of the semiconductor substrate may be p-type conductivity. Also, the material of the semiconductor substrate may be a GaAs or InP compound semiconductor. The thickness of the semiconductor substrate 10 is preferably from 20 μm to 500 μm, and more preferably from 50 μm to 300 μm.

The semiconductor substrate 10 has a light-receiving surface 10a and a back surface 10b. Semiconductor layer 12 and semiconductor layer 13 are arranged on a portion of the back surface 10b.

Semiconductor layer 12 has an n-type semiconductor layer 12n, which has the same type of conductivity as the semiconductor substrate 10, and an i-type semiconductor layer 12i. The n-type semiconductor layer 12n is a semiconductor layer containing an n-type dopant. The n-type semiconductor layer 12n can also be made of amorphous silicon containing an n-type dopant. The thickness of the n-type semiconductor layer 12n is preferably from 2 nm to 50 nm, and more preferably from 4 nm to 30 nm. The n-type semiconductor layer 12n generates an electric field with the semiconductor substrate 10 which pushes the minority carriers generated in the semiconductor substrate 10 from received light that are diffused towards the n-type semiconductor layer 12n back towards the semiconductor substrate 10.

An i-type semiconductor layer 12i is arranged between the n-type semiconductor layer 12n and the back surface 10b. The i-type semiconductor layer 12i can be made from i-type amorphous silicon. The i-type semiconductor layer 12i can be of any thickness as long as the thickness keeps it from contributing substantially to power generation. The thickness of the i-type semiconductor layer 12i can be from several Å to 250 Å.

Both semiconductor layers 12n, 12i preferably contain hydrogen.

Semiconductor layer 13 has a p-type semiconductor layer 13p, which has a type of conductivity different from that of semiconductor substrate 10, and an i-type semiconductor layer 13i. The p-type semiconductor layer 13p is a semiconductor layer containing a p-type dopant. The p-type semiconductor layer 13p can also be made of amorphous silicon containing a p-type dopant. The thickness of the p-type semiconductor layer 13p is preferably from 1 nm to 40 nm, and more preferably from 2 nm to 20 nm. The p-type semiconductor layer 13p generates an electric field with the semiconductor substrate 10 which isolates the carriers generated in the semiconductor substrate 10 from received light.

The i-type semiconductor layer 13i is arranged between the p-type semiconductor layer 13p and the back surface 10b. The i-type semiconductor layer 13i can be made from i-type amorphous silicon. The i-type semiconductor layer 13i can be of any thickness as long as the thickness keeps it from contributing substantially to power generation. The thickness of the i-type semiconductor layer 13i can be from several Å to 250 Å.

Both semiconductor layers 13p, 13i preferably contain hydrogen. When the semiconductor layers 13p, 13i contain hydrogen, the concentration of hydrogen in semiconductor layers 13p, 13i is preferably lower than the concentration of hydrogen in semiconductor layers 12n, 12i.

In the present invention, an “n-type semiconductor layer” is a semiconductor layer having an n-type dopant content equal to or greater than 5×10¹⁹ cm⁻³.

A “p-type semiconductor layer” is a semiconductor layer having a p-type dopant content equal to or greater than 5×10¹⁹ cm⁻³.

An “i-type semiconductor layer” is a semiconductor layer having an n-type dopant content or p-type dopant content less than 1×10¹⁹cm⁻³.

Both semiconductor layer 12 and semiconductor layer 13 have a plurality of linear portions 12a, 13a extending in one direction (the y direction). The linear portions 12a, 13a are arranged in the direction (the x direction) perpendicular to the one direction. The linear portions 12a and 13a adjacent to each other in the x direction come into contact with each other. In the present invention, the entire back surface 10b is substantially covered by semiconductor layers 12 and 13. Both the width W1 of the linear portions 12a of the semiconductor layer 12 (=the interval between linear portions 13a of the semiconductor layer 13 adjacent to each other in the x direction) and the width W2 of the linear portions 13a of the semiconductor layer 13 (=the interval between linear portions 12a of the semiconductor layer 12 adjacent to each other in the x direction) are preferably from 50 μm to 2000 μm, and more preferably from 100 μm to 1000 μm.

An insulating layer 18 is formed on both ends of each linear portion 12a in the x direction, excluding the central portion. The central portion of the linear portions 12a in the x direction remains exposed from the insulating layer 18. The end portions of the semiconductor layer 12 in the x direction and the end portions of the semiconductor layer 13 in the x direction are separated from each other by the insulating layer 18 in the thickness direction (z direction).

There is no particular restriction on the width W3 of the insulating layer 18 in the x direction, and it can be, for example, approximately one-third of width W1. There is no particular restriction on the interval W4 in the insulating layer 18 in the x direction. It can be, for example, approximately one-third of width W1.

There are no particular restrictions on the materials in insulating layer 18. The insulating layer 18, for example, can be formed from a silicon oxide such as SiO₂, a silicon nitride such as SiN, or a silicon oxynitride such as SiON. The insulating layer 18 can also be made of a metal oxide such as titanium oxide or tantalum oxide. Among these examples, an insulating layer 18 made of silicon nitride is preferred. The insulating layer 18 also preferably contains hydrogen.

An n-type semiconductor layer 17n, which has the same conductivity as the semiconductor substrate 10, is arranged on the light-receiving surface 10a of the semiconductor substrate 10. The n-type semiconductor layer 17n is a semiconductor layer containing an n-type dopant. The n-type semiconductor layer 17n can be made of amorphous silicon containing an n-type dopant. The thickness of the n-type semiconductor layer 17n is preferably from 2 nm to 50 nm, and more preferably from 5 nm to 30 nm.

An i-type semiconductor layer 17i is arranged between the n-type semiconductor layer 17n and the light-receiving surface 10a. The i-type semiconductor layer 17i can be made from i-type amorphous silicon. The i-type semiconductor layer 17i can be of any thickness as long as the thickness keeps it from contributing substantially to power generation. The thickness of the i-type semiconductor layer 17i can be from several Å to 250 Å.

An insulating film 16 combining the functions of an anti-reflective film and a protective film is formed on the semiconductor layer 17n. The insulating layer 16 can be formed from a silicon oxide such as SiO₂, a silicon nitride such as SiN, or a silicon oxynitride such as SiON. The thickness of the insulating layer 16 can be designed, as appropriate, in accordance with the desired anti-reflective properties of an anti-reflective film. The thickness of the insulating layer 16 can be, for example, from 80 nm to 1 μm.

There is no light-blocking metal film provided on the light-receiving surface 10a. As a result, light can be received over the entire light-receiving surface 10a.

An n-side electrode 14 is arranged on the semiconductor layer 12. The n-side electrode 14 is connected electrically to the semiconductor layer 12. A p-side electrode 15 is arranged on the semiconductor layer 13. The p-side electrode 15 is connected electrically to the semiconductor layer 13. The n-side electrode 14 and the p-side electrode 15 are separated electrically on the insulating layer 18. The interval W5 between electrodes 14 and 15 in the insulating layer 18 can be, for example, approximately one-third of width W3.

In the present embodiment, both the n-side electrode 14 and the p-side electrode 15 are comb-shaped and include a busbar and a plurality of fingers. However, the n-side electrode 14 and the p-side electrode 15 may also be so-called busbarless electrodes which have no busbar but only a plurality of fingers.

The electrodes 14 and 15 can be formed from a metal such as Cu or Ag, or an alloy including at least one of these metals. The electrodes 14 and 15 can also be formed from a transparent conductive oxide (TCO) such as indium tin oxide (ITO). The electrodes 14 and 15 can also made of a laminate having a plurality of conductive layers comprising metal, alloy or TCO layers. When the electrodes 14 and 15 include a TCO layer, the TCO layer is preferably arranged so as to come into contact with the semiconductor layers 12 and 13.

In the present embodiment, the p-type semiconductor layer 13p, which has a type of conductivity (p-type) different from the n-type semiconductor substrate 10, is thinner than the n-type semiconductor layer 12n, which has the same type of conductivity (n-type) as the semiconductor substrate 10. In other words, the p-type semiconductor layer 13p is relatively thin, and the n-type semiconductor layer 12n is relatively thick. This effectively suppresses the loss of minority carriers (holes) to rebonding by the relatively thick n-type semiconductor layer 12n. Because the field strength formed by the relatively thick n-type semiconductor layer 12n is great, the holes are effectively directed towards the p-side electrode 15. Because the p-type semiconductor layer 13p is relatively thin, the electrical resistance between the semiconductor substrate 10 and the p-side electrode 15 is low. Therefore, improved collection efficiency can be realized. As a result, improved photoelectric conversion efficiency can be obtained.

Also, in the present embodiment, the width (W1) of the linear portions 12a of the semiconductor layer 12 in the x direction is smaller than the width (W2) of the linear portions 13a of the semiconductor layer 13 in the x direction. As a result, the width (W1) of the linear portions 12a of the semiconductor layer 12 is narrow. This reduces the distance that the holes generated below the semiconductor layer 12 on the semiconductor substrate 10 must to travel to be collected by the p-side electrode 15. Therefore, even better collection efficiency can be realized.

In the present embodiment, the n-type semiconductor layer 12n contains hydrogen. As a result, the bandgap of the n-type semiconductor layer 12n is great. This more effectively suppresses bonding of the holes by the n-type semiconductor layer 12n. Therefore, even better collection efficiency can be realized.

In the present embodiment, an i-type semiconductor layer 12i is arranged between the n-type semiconductor layer 12n and the semiconductor substrate 10. This effectively suppresses rebonding of the holes beneath the n-type semiconductor layer 12n on the semiconductor substrate 10. Therefore, even better collection efficiency can be realized.

In the present embodiment, the i-type semiconductor layer 12i contains hydrogen. As a result, the bandgap of the i-type semiconductor layer 12i is great. This more effectively suppresses bonding of the holes by the i-type semiconductor layer 12i. Therefore, even better collection efficiency can be realized.

An i-type semiconductor layer 13i is arranged between the p-type semiconductor layer 13p and the semiconductor substrate 10. For this reason, rebonding of the carriers can be more effectively suppressed. The i-type semiconductor layer 13i is thinner than the i-type semiconductor layer 12i. This suppresses any increase in the electrical resistance between the semiconductor substrate 10 and the p-side electrode 15. Therefore, even better collection efficiency can be realized.

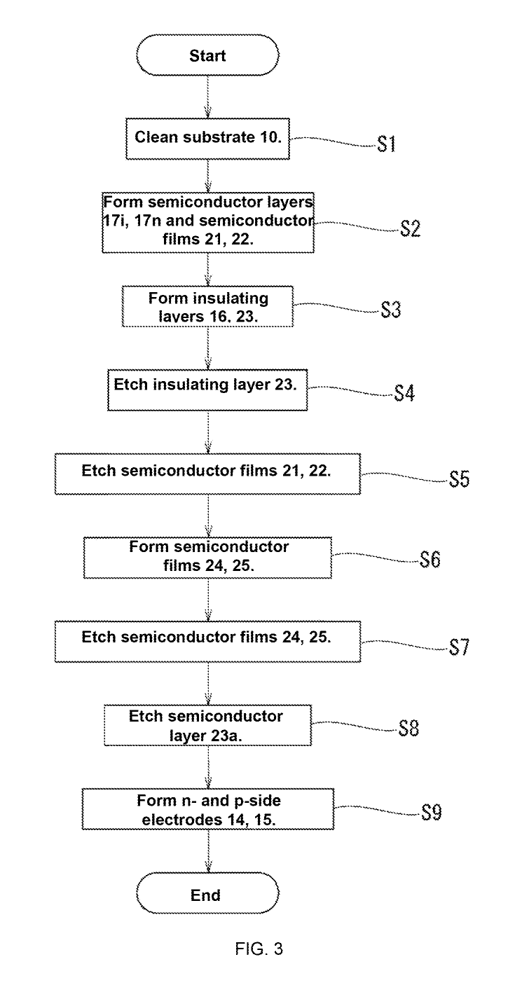

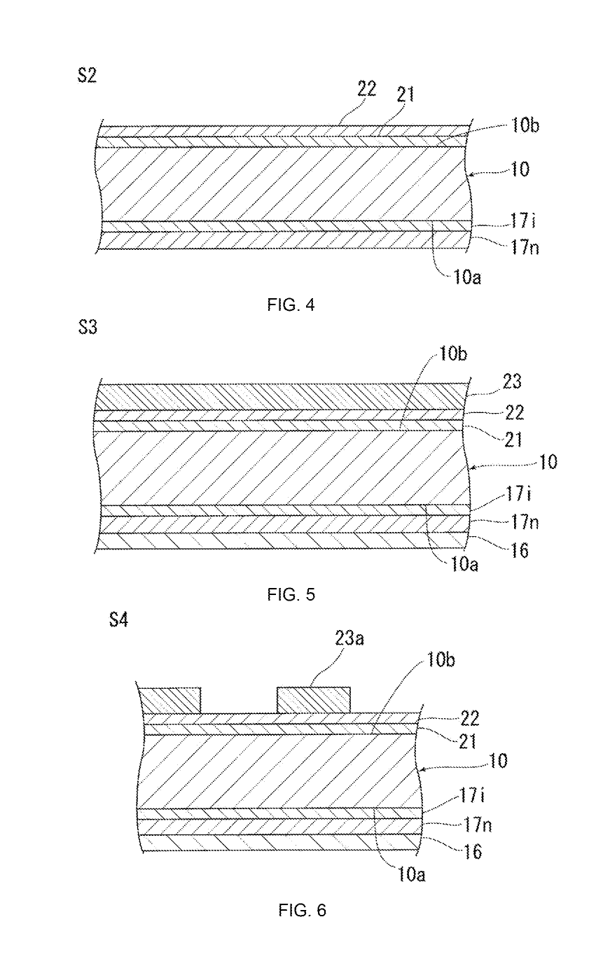

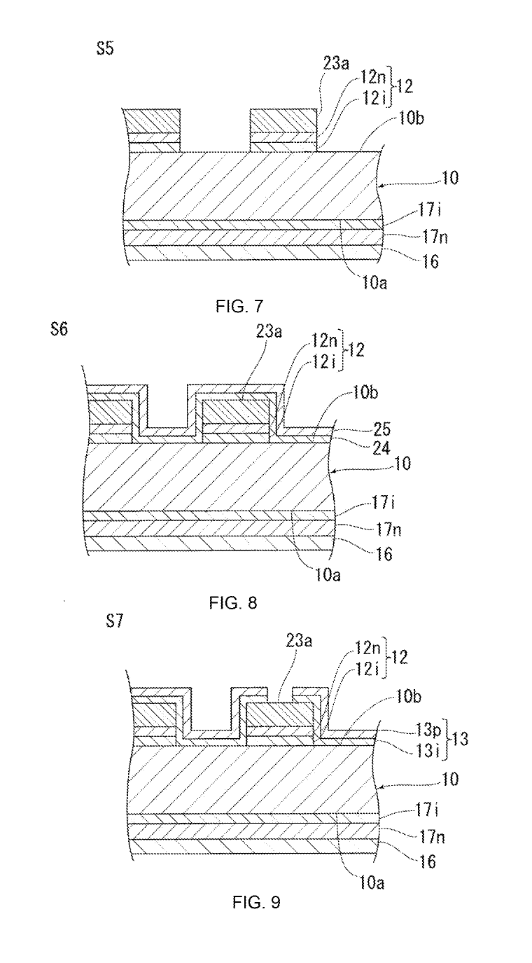

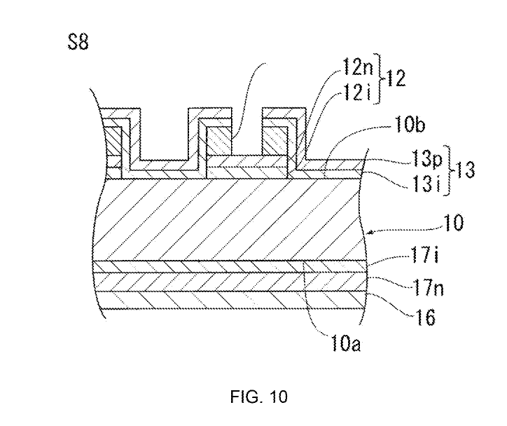

The following is an explanation of the manufacturing method for the solar cell 1 in the present embodiment with reference primarily to FIG. 3 through FIG. 10.

First, the semiconductor substrate 10 is prepared. Next, in Step 51, the light-receiving surface 10a and the back surface 10b of the semiconductor substrate 10 are cleaned. The semiconductor substrate 10 can be cleaned using, for example, an aqueous HF solution. In this step, texturing is formed on the light-receiving surface 10a of the semiconductor substrate 10 using a method such as alkali etching, acid etching or dry etching. In this event, the texturing formed on the back surface 10b is smaller than the texturing provided on the light-receiving surface 10a. Alternatively, the back surface 10b does not have to be textured.

Next, in Step S2, semiconductor layer 17i and semiconductor layer 17n are formed on the light-receiving surface 10a of the semiconductor substrate 10, and i-type amorphous semiconductor film 21 and n-type amorphous semiconductor film 22 are formed on the back surface 10b.

There are no restrictions on the method used to form semiconductor layers 17i and 17n and semiconductor films 21 and 22. Semiconductor layers 17i and 17n and semiconductor films 21 and 22 can be formed using a chemical vapor deposition (CVD) method such as a plasma CVD method, or another thin-film forming method such as a sputtering method.

Next, in Step S3, an insulating layer 16 is formed on the semiconductor layer 17n, and an insulating layer 23 is formed on semiconductor film 22. There are no restrictions on the method used to form the insulating layers 16 and 23. The insulating layers 16 and 23 can be formed, for example, using a thin-film forming method such as a sputtering method or a CVD method.

Next, in Step S4, a portion of insulating layer 23 is removed by etching the insulating layer 23. More specifically, the portion of the insulating layer 23 above the region where the p-type semiconductor layer is bonded to the semiconductor substrate 10 in a later step is removed. In this way, insulating layer 23a is formed. When the insulating layer 23 comprises silicon oxide, silicon nitride or silicon oxynitride, the insulating layer 23 can be etched using an acidic etching solution such as an aqueous HF solution.

Next, in Step S5, the insulating layer 23a is used as a mask, and semiconductor film 21 and semiconductor film 22 are etched to remove the portion of semiconductor film 21 and semiconductor film 22 not covered by the insulating layer 23a. In this way, the portion of the back surface 10b not covered by the insulating layer 23a is exposed, and semiconductor layers 12i and 12n are formed from semiconductor film 21 and 22, respectively. Semiconductor film 21 and 22 can be etched using an alkaline etching solution.

Next, in Step S6, i-type amorphous semiconductor film 24 and p-type amorphous semiconductor film 25 are formed in successive order to cover the back surface 10b including the n-type semiconductor layer 12n. There are no restrictions on the method used to form amorphous semiconductor film 24 and 25. Amorphous semiconductor film 24 and 25 can be formed, for example, using a thin-film forming method such as a sputtering method or a CVD method.

Next, in Step S7, one part of the portion of semiconductor films 24 and 25 that is positioned on the insulating layer 23a is etched. In this way, semiconductor layers 13i and 13p are formed from amorphous semiconductor films 24 and 25, respectively. Semiconductor films 24 and 25 can be etched using an aqueous NaOH solution.

Next, in Step S8, the insulating layer 23a is etched. More specifically, the exposed portion of the insulating layer 23a is removed by etching from the top of semiconductor layers 12i and 12n. This exposes the semiconductor layer 12n and forms insulating layer 18 from insulating layer 23a. Insulating layer 23a can be etched using an aqueous HF solution.

Next, in Step S9, the solar cell 1 is completed by forming the electrodes 14 and 15 on semiconductor layer 12n and semiconductor layer 13p, respectively.

In the present embodiment, the relatively thin p-type semiconductor layer 13p is formed after the relatively thick n-type semiconductor layer 12n has been formed. In the event of forming the insulating layer 23 on the semiconductor layers, it is possible to form an altered layer such as an oxidized layer or nitrided layer on the surface of the semiconductor layers. The adverse effects of the altered layer depend largely on the thinness of the layers. Therefore, in the present invention, the relatively thin p-type semiconductor layer 13p is formed after the relatively thick n-type semiconductor layer 12n has been formed. This can reduce the adverse effects of the altered layer on the relatively thin p-type semiconductor layer 13p. As a result, better photoelectric conversion efficiency can be obtained.

The present invention includes many other embodiments not described herein. For example, the semiconductor substrate may be a p-type semiconductor substrate. In this case, the thickness of the n-type semiconductor layer, which has a type of conductivity different from that of the semiconductor substrate, must be thinner than the thickness of the p-type semiconductor layer, which has the same type of conductivity as the semiconductor substrate. Therefore, the technical scope of the present invention is defined solely by the items of the invention specified in the claims pertinent to the above explanation.

### KEY TO THE DRAWINGS

1: solar cell

10: semiconductor substrate

12, 13: semiconductor layers

12a, 13a: linear portions

12i, 13i: i-type semiconductor layer

12n: n-type semiconductor layer

13p: p-type semiconductor layer

14: n-side electrode

15: p-side electrode

What is claimed is:

1. A solar cell comprising:
a semiconductor substrate having one type of conductivity;
a first semiconductor substrate having the one type of conductivity arranged on one main surface of the semiconductor substrate;
a second semiconductor substrate having the other type of conductivity arranged on the one main surface of the semiconductor substrate;
a first electrode connected electrically to the first semiconductor layer; and
a second electrode connected electrically to the second semiconductor layer;
the thickness of the second semiconductor layer being thinner than the thickness of the first semiconductor layer.

2. The solar cell according to claim 1, wherein the first and second semiconductor layers each have a plurality of linear portions, the width of the linear portions of the first semiconductor layer being smaller than the width of the linear portions of the second semiconductor layer.

3. The solar cell according to claim 1, wherein the first semiconductor layer contains hydrogen.

4. The solar cell according to claim 1, wherein a first i-type semiconductor layer is further provided between the first semiconductor layer and the semiconductor substrate.

5. The solar cell according to claim 4, wherein a second i-type semiconductor layer is arranged between the second semiconductor layer and the semiconductor substrate, the second i-type semiconductor layer being thinner than the first i-type semiconductor layer.

6. The solar cell according to claim 1, wherein the other main surface of the semiconductor substrate is the light-receiving surface.

7. A method for manufacturing a solar cell comprising the steps of:
forming a first semiconductor layer having one type of conductivity on a portion of one main surface of a semiconductor substrate having the one type of conductivity;
forming a semiconductor film having the other type of conductivity on the one main surface of the semiconductor substrate including the first semiconductor layer;
exposing the first semiconductor layer by removing at least one part of the portion of the semiconductor film positioned on the first semiconductor layer, and forming a second semiconductor layer from the semiconductor film; and
forming a first electrode on the first semiconductor layer, and a second electrode on the second semiconductor layer;
the thickness of the second semiconductor layer being thinner than the thickness of the first semiconductor layer.
